(19) United States
(12) Patent Application Publication
(10) Pub. No.: US 2006/0099449 A1
(43) Pub. Date: May 11, 2006

(54) Light-emitting device

(75) Inventors: Akio Amano, Kawasaki-shi (JP); Hiroki Iwanaga, Yokohama-shi (JP); Koichi Harada, Tokyo (JP)

Correspondence Address: AMIN & TUROCY, LLP, 1900 EAST 9TH STREET, NATIONAL CITY CENTER, 24TH FLOOR,, CLEVELAND, OH, 44114, US

(73) Assignee: Kabushiki Kaisha Toshiba, Minato-ku (JP)

(21) Appl. No.: 11/268,035

(22) Filed: Nov. 7, 2005

(30) Foreign Application Priority Data
Nov. 9, 2004 (JP) 2004-324883

(51) Int. Cl. H01L 51/52; H05B 33/02

(52) U.S. Cl. 428/690; 428/917; 428/212; 313/504; 313/506; 257/E51.044; 257/98

(57) ABSTRACT

A light-emitting device is provided, which includes a light-emitting element configured to emit light, a first fluorescent layer comprising an inorganic fluorescent substance, formed on the light-emitting element and having a first refractive index, and a second fluorescent layer comprising an organic fluorescent substance, formed above the first fluorescent layer and having a second refractive index.

### CROSS-REFERENCE TO RELATED APPLICATIONS

This application is based upon and claims the benefit of priority from prior Japanese Patent Application No. 2004-324883, filed Nov. 9, 2004, the entire contents of which are incorporated herein by reference.

### BACKGROUND OF THE INVENTION

1. Field of the Invention

The present invention relates to a light-emitting device, particularly, to a light-emitting device using an LED element.

2. Description of the Related Art

In recent years, an LED attracts attention in the market of illuminating devices as a new light source in view of the diversification of the use and the environment of use, enhanced demands for an improved design, and an environmental aspect. Nowadays, the emission efficiency of an LED in which an inorganic fluorescent substance is used for forming the light-emitting layer is being drastically improved and is said to shortly exceed the emission efficiency of the fluorescent lamp.

Where an LED is used in an illuminating apparatus, the LED is required to exhibit excellent characteristics not only in the emission efficiency but also in color rendering properties and color purity, depending on the use of the illuminating apparatus. However, the LED using an inorganic fluorescent substance alone, which is available nowadays, is incapable of satisfying all of these characteristics simultaneously. Also, since fine particles of the fluorescent substance are dispersed in the fluorescent layer, the light is scattered so as to make it unavoidable for the light extraction efficiency to be lowered. Where the LED device is manufactured by using an inorganic fluorescent substance, the emission intensity is improved with increase in the amount of the inorganic fluorescent substance. However, if the content of the inorganic fluorescent substance exceeds a certain value, the light-scattering effect produced by the inorganic fluorescent substance itself causes the light extraction efficiency to be lowered, with the result that the emission intensity is lowered.

On the other hand, the concept of using an organic fluorescent substance for the manufacture of an LED (organic LED) is already known to the art. However, the organic LED has not yet been put to practical use in the illuminating apparatus because of the following problems.

(1) In the case of using an organic fluorescent substance for emitting luminescence of R, G, B with the near-ultraviolet LED, which is most common nowadays, used as a light source, the organic compound is prominently deteriorated by the ultraviolet light, because the organic compound is weak in general against the ultraviolet light. Particularly, where there is an absorption based on the n-π* transition in the near-ultraviolet region, the organic compound is quickly deteriorated.

(2) In the organic fluorescent substance, it is possible for the spectrum of the fluorescence to be changed depending on the concentration of the organic fluorescent substance, and it is difficult to control the spectrum. Also, the fluorescence intensity is dependent on the concentration of the fluorescent substance. In the high concentration region, concentration quenching phenomenon takes place.

(3) The spectrum of fluorescence is changed depending on the kind of the polymer in which the organic fluorescent substance is dispersed.

On the other hand, a rare earth element complex is advantageous over an ordinary organic fluorescent substance, as pointed out below. Structural formula (1) given below exemplifies the chemical structure of a rare earth element complex used in a low molecular weight organic EL element:

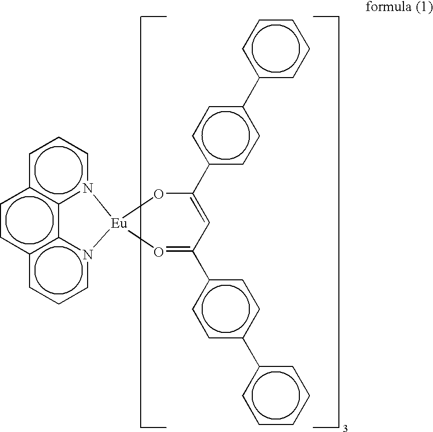

In the compound represented by structural formula (1), ligands are formed of phenanthroline and β-diketones. Phenanthroline absorbs light so as to form the excited state, with the result that energy transfer is brought about from the triplet excited state into the central atom of europium so as to obtain emission of luminescence having a wavelength of 612 nm, which is peculiar to europium. Since phenanthroline performs light absorption, the absorption coefficient is large so as to increase the emission intensity. The particular compound is advantageous over the ordinary organic compound, as pointed out below:

(1) The emission wavelength is peculiar to the rare earth element, and the spectrum of fluorescence is not affected by the concentration of the fluorescent substance and the kind of the polymer in which the fluorescent substance is dispersed, with the result that the spectrum of fluorescence is stable.

(2) The ligand is formed of an organic compound. However, if the ligand absorbs light so as to be excited, the energy state is brought back to the ground state by the energy transfer to the central atom so as to decrease the opportunity of bringing about an irreversible chemical change from the excited state. It follows that the durability against ultraviolet light is expected to be improved.

(3) In dispersing the rare earth element complex in a polymer, it is possible to disperse the particles of the rare earth element complex in the polymer on the molecular level by selecting a combination of a rare earth element complex and a polymer in view of the compatibility between the two. It follows that it is possible to form a polymer film that is transparent to visible light and small in light scattering.

Where a white LED device is to be manufactured by using an organic fluorescent substance, sufficient light emission characteristics are not obtained nowadays except for red light. Therefore, it is necessary to realize the white light emission by using an organic fluorescent substance in combination with an inorganic fluorescent substance. However, where an organic fluorescent substance and an inorganic fluorescent substance are used in combination, a light scattering effect is generated in the inorganic fluorescent substance in spite of the situation that it is possible to make transparent the light-emitting layer only using the organic fluorescent substance. Such being the situation, it is impossible to set forth sufficiently the characteristics of the organic fluorescent substance.

Also, proposed is a laminate structure comprising a semiconductor light-emitting element such as an LED or an LD, a first fluorescent layer containing a first fluorescent substance and formed on the semiconductor light-emitting element, and a second fluorescent layer containing the second fluorescent substance emitting luminescence having a wavelength shorter than that of the luminescence emitted from the first fluorescent substance contained in the first fluorescent layer. It is proposed that the first fluorescent layer is arranged closer to the semiconductor light-emitting element than the second fluorescent layer.

As described above, in the conventional white LED in which the single light-emitting layer is formed by using an organic fluorescent substance and an inorganic fluorescent substance in combination, it was impossible to set forth sufficiently the characteristics of the organic fluorescent substance. Further, since the organic fluorescent substance itself does not have a high durability, it was impossible to improve the resistance of the light-emitting device to ultraviolet light and to improve the resistance of the light-emitting device to heat. It follows that it was impossible to realize a light-emitting device having a high reliability, a high efficiency and high color rendering properties.

### BRIEF SUMMARY OF THE INVENTION

A light-emitting device according to one aspect of the present invention comprises a light-emitting element configured to emit light; a first fluorescent layer comprising an inorganic fluorescent substance, formed on the light-emitting element and having a first refractive index; and a second fluorescent layer comprising an organic fluorescent substance, formed above the first fluorescent layer and having a second refractive index.

### BRIEF DESCRIPTION OF THE SEVERAL VIEWS OF THE DRAWING

FIGS. 1A, 1B and 1C are cross sectional views schematically showing the construction of a light-emitting device according to one embodiment of the present invention and a light-emitting device for a Comparative Example; and

FIGS. 2A, 2B and 2C are cross sectional views schematically showing the constructions of light-emitting devices according to the third and fourth embodiments of the present invention.

### DETAILED DESCRIPTION OF THE INVENTION

As a result of an extensive research on the subject matter described above, the present inventors have found that the light-emitting device of the construction described in the following makes it possible to improve markedly the reliability. Specifically, the light-emitting device noted above is constructed such that a second fluorescent layer containing an organic fluorescent substance is arranged apart from the light-emitting section, and a first fluorescent layer containing an inorganic fluorescent substance is arranged between the light-emitting section and the second fluorescent layer.

In the light-emitting device using a fluorescent layer containing an inorganic fluorescent substance, the emission intensity is improved with an increase in the concentration of the inorganic fluorescent substance and in the thickness of the inorganic fluorescent layer. However, the increase in the emission intensity is maximum at a prescribed value and, then, is decreased moderately. It is considered reasonable to understand that this tendency is caused by a trade-off, i.e., the emission intensity is improved by, for example, the increase in the concentration of the fluorescent substance, but the increase in the amount of the fine particles causes the light scattering effect to be increased so as to lower the light extraction efficiency. On the other hand, in the case of using a fluorescent layer containing an organic fluorescent substance, the light scattering effect is not generated. As a result, the emission intensity is increased with increase in the concentration of the organic fluorescent substance and in the thickness of the organic fluorescent layer to the point of saturation at a prescribed value.

Also, the UV leakage behavior tends to be decreased with increase in the concentration of the fluorescent substance and in the thickness of the fluorescent layer in respect of each of the inorganic fluorescent substance and the organic fluorescent substance. It is necessary to control appropriately the concentration of the inorganic fluorescent substance in the inorganic fluorescent layer and the thickness of the inorganic fluorescent layer in view of, for example, the concentration-emission intensity characteristics. Oh the other hand, in the case of an organic fluorescent layer, the emission intensity is saturated in the case where the concentration of the organic fluorescent substance in the organic fluorescent layer is not lower than a prescribed concentration or where the thickness of the organic fluorescent layer is not smaller than a prescribed thickness and, thus, the emission intensity can be regarded as having a prescribed value. Such being the situation, it is considered reasonable to understand that the organic fluorescent layer performs the function of a layer that serves to suppress the UV leakage without giving a big influence on the color phase even if the organic fluorescent layer is formed on an inorganic fluorescent layer to a thickness not smaller than a prescribed thickness.

Under the circumstances, if the light-emitting device is formed by laminating a first fluorescent layer containing an inorganic fluorescent substance and a second fluorescent layer containing an organic fluorescent substance, it is possible to utilize effectively each of the fluorescent layers so as to make it possible to provide a light-emitting device excellent in efficiency and in color rendering properties.

Also, according to the embodiment of the present invention, it is possible to suppress the deterioration of the organic fluorescent substance contained in the second fluorescent layer by arranging the second fluorescent layer containing the organic fluorescent substance apart from the light-emitting section.

What should also be noted is that the first fluorescent layer containing an inorganic fluorescent substance is formed before formation of the second fluorescent layer containing an organic fluorescent substance. It follows that, in curing the matrix polymer constituting the first fluorescent layer, it is possible to avoid the problem that the second fluorescent layer is damaged so as to be deteriorated. Where a silicone resin is used as the matrix polymer of the first fluorescent layer, it is possible to avoid the problem that the silicone monomer radical attacks the organic fluorescent substance contained in the second fluorescent layer in curing the matrix polymer so as to deteriorate the quality of the light-emitting device.

As pointed out above, it is possible to maintain transparent the second fluorescent layer containing an organic fluorescent substance, with the result that it is possible to provide a light-emitting device having a high reliability.

Some embodiments of the present invention will now be described with reference to the accompanying drawings.

### First Embodiment

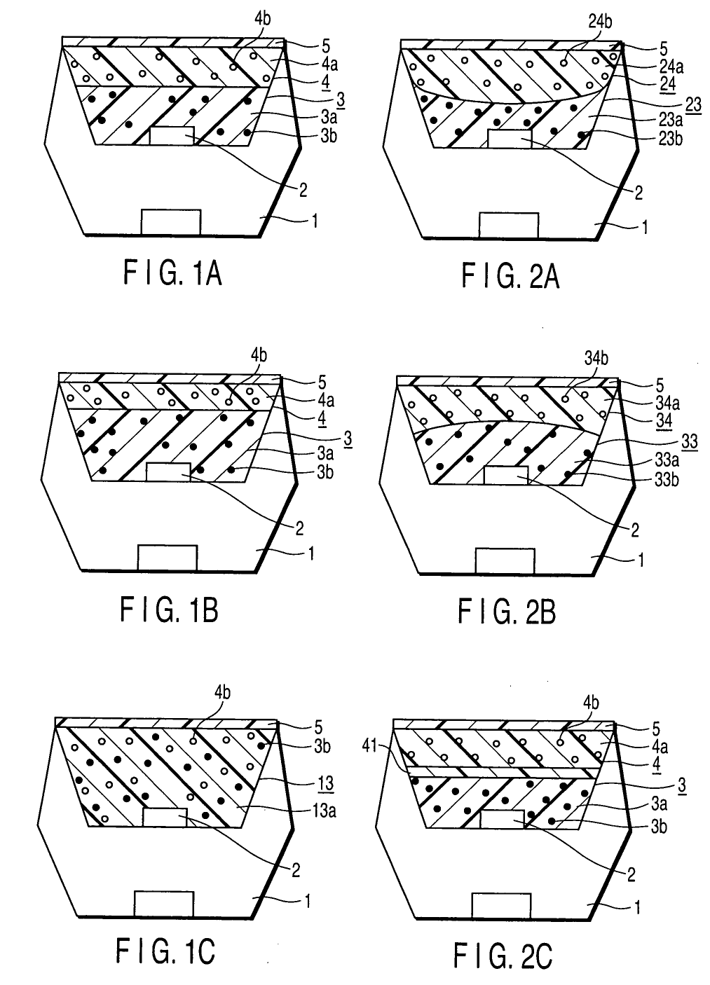

FIGS. 1A and 1B are cross sectional views collectively showing the construction of a light-emitting device according to the first embodiment of the present invention. The light-emitting device shown in FIGS. 1A and 1B, in which an LED is used as a light-emitting section, includes a laminate structure comprising an inorganic fluorescent layer and an organic fluorescent layer. To be more specific, an LED chip used as a light-emitting section 2 is arranged within a recess of an LED frame 1, as shown in FIGS. 1A and 1B. The LED chip 2 is formed of, for example, a GaN-based semiconductor material, and emits an ultraviolet light having the wavelength of 395 nm, for example. The light-emitting section 2 is not limited to an LED chip. It is also possible to use, for example, an ultraviolet light emitting device such as a laser diode. Incidentally, a pair of electrodes (not shown) are mounted to the LED chip 2.

An inorganic fluorescent layer 3 and an organic fluorescent layer 4 are laminated one upon the other on the LED chip 2 within the recess of the LED frame 1. Particles 3b of an inorganic fluorescent substance are dispersed in a silicone resin 3a so as to form the inorganic fluorescent layer 3 occupying a lower part of the recess of the LED frame 1. The particle 3b of the inorganic fluorescent substance is formed of InGaN that emits luminescence of green having a wavelength of 520 nm and/or InGaN that emits luminescence of blue having a wavelength of 450 nm. On the other hand, the organic fluorescent layer 4 is formed of a matrix polymer 4a having particles 4b of a rare earth complex dispersed therein and constitutes the remaining upper region of the recess of the LED frame 1. It is possible to use a compound represented by, for example, the following general formula as the particle 4b of the rare earth element complex:

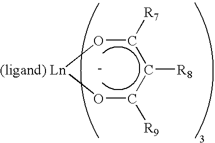

where Ln denotes an alkaline earth atom, each of R₇ and R₉, which are the same or different, is selected from the group consisting of a linear or branched alkyl group, a linear or branched alkoxy group, a phenyl group, a biphenyl group, a naphthyl group, a hetero-ring group and a derivative thereof. At least one hydrogen atom of each group may be substituted with a substituent to form a substituted group. The substituted group is referred as a derivative in this specification. R₈ is selected from the group consisting of a halogen atom, a heavy hydrogen atom, and a linear or branched aliphatic hydrocarbon group having 1 to 22 carbon atoms.

It is desirable for the rare earth element complex 4b to be represented by the general formula given below:

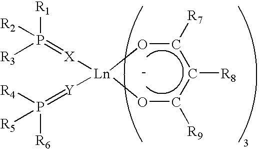

where Ln denotes a rare earth atom, each of X and Y, which may be the same or different, is an atom selected from the group consisting of O, S and Se, each of R₁ to R₆, which may be the same of different, is selected from the group consisting of a linear or branched alkyl group having not larger than 20 carbon atoms, a linear or branched alkoxy group having not larger than 20 carbon atoms, a phenyl group, a biphenyl group, a naphthyl group, a hetero ring group, and derivatives thereof, the combination of R₁ to R₃ differing from the combination of R₄ to R₆, each of R₇ and R₉, which may be the same or different, is selected from the group consisting of a linear or branched alkyl group, a linear or branched alkoxy group, a phenyl group, a biphenyl group, a naphthyl group, a hetero ring group and derivatives thereof, and R₈ is selected from the group consisting of a halogen atom, a heavy hydrogen atom, and a linear or branched aliphatic hydrocarbon group having 1 to 22 carbon atoms.

It is possible for the rare earth element atom Ln to be selected from the group consisting of europium, terbium, iridium and erbium. It is particularly desirable for europium to be used as the rare earth element atom because europium permits realizing a fluorescent substance capable of a red light emission with a high efficiency, though a red light emission is not achieved in the LED fluorescent substance available nowadays. To be more specific, it is particularly desirable to use a rare earth element complex represented by structural formula (2) given below. Since the europium complex of the particular construction has an asymmetric structure, it is possible to obtain luminescence with a high emission efficiency.

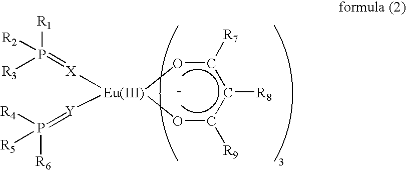

where X, Y and R₁ to R₉ are as defined above.

Structural formula (3) given below exemplifies the europium complex represented by structural formula (2) given above:

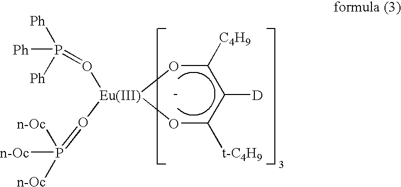

On the other hand, the matrix polymer 4a includes, for example, polytetrafluoro ethylene, tetrafluoroethylene-perfluoroalkyl vinyl ether copolymer, tetrafluoroethylene-hexafluoro propylene copolymer, tetrafluoroethylene-ethylene copolymer, polyvinylidene fluoride, poly-chlorotrifluoroethylene, fluoroethylene-vinyl ether copolymer, a copolymer between the fluorocarbon resin noted above and an acrylic resin, and a fluorinated acrylic resin.

In view of the dispersion capability of an organic fluorescent substance, compatibility with an organic fluorescent substance, and the ease of handling, it is particularly desirable to use fluoroethylene-vinyl ether copolymer, the fluorocarbon-acrylic resin copolymer, and the fluorinated acrylic resin as the matrix polymer 4a.

In the embodiment of the present invention, the europium complex represented by structural formula (3) given above is used as the rare earth element complex, and the fluorine-based polymer is used as the matrix polymer 4a. The fluorine-based polymer includes, for example, “Cefral” (trade name, manufactured by Central Glass Co., Ltd.).

In general, the fluorine-based polymer is not dissolved in a solvent other than the fluorine-based solvent, and a polar compound such as a coloring matter is not dissolved in the fluorine-based solvent. Therefore, it is difficult to disperse uniformly the rare earth element complex in the fluorine-based polymer. However, in the case of using a copolymer of a fluorine-based polymer such as a fluorine-based acrylic polymer, it is possible to dissolve the polymer in various solvents so as to make it possible to enhance the compatibility with the rare earth element complex. It is possible to disperse the europium complex represented by structural formula (2) given previously in the fluorine-based polymer noted above so as to form a fluorescent layer exhibiting a sufficient emission intensity.

The fluorine-based polymer noted above satisfies characteristics (1) to (7) given below. These characteristics are important for forming a light-emitting device using an LED.

(1) The fluorine-based polymer exhibits a high light transmittance in the visible and near ultraviolet regions.

(2) The fluorine-based polymer is photochemically stable.

(3) The fluorine-based polymer is unlikely to bring about an oxidizing reaction.

(4) The fluorine-based polymer has a high glass transition point (preferably not lower than 100° C.).

(5) The fluorine-based polymer exhibits high oxygen shutoff properties.

(6) The fluorine-based polymer exhibits high moisture preventing properties.

(7) The fluorine-based polymer does not have a C—H bond and an O—H bond, or the amount of the C—H bond and the O—H bond included in the fluorine-based polymer is small.

The fluorine-based polymers satisfying characteristics (1) to (7) given above and highly compatible with the rare earth element complex include, for example, Teflon (R) AF manufactured by Du Pont Inc., LUMIFLON manufactured by Asahi Glass Co. Ltd., and fluorine-based acrylic resins in addition to Cefral noted above. These polymers can be dissolved in a solvent so as to be used in the form of an ink.

Also, it is possible to use a complex having a structural formula (4) given below in addition to the europium complex represented by structural formula (2) given previously, as disclosed in Japanese Patent Application No. 2003-179811 filed previously by the present applicant. The complex represented by structural formula (4) can be dispersed satisfactorily in the fluorine-based polymer described above. Further, since the complex represented by structural formula (4) has an asymmetric structure, it is possible to obtain a light emission with a high efficiency.

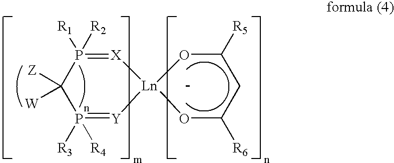

where Ln denotes a rare earth element, each of X and Y is an atom selected from the group consisting of O, S and Se, each of R₁ to R₆ is selected from the group consisting of a linear or branched alkyl group having not larger than 20 carbon atoms, a linear or branched alkoxy group having not larger than 20 carbon atoms, a phenyl group, a biphenyl group, a naphthyl group, a hetero ring group, and derivatives thereof, with the proviso that it is excluded where all of R₁ to R₄ to be the same, n is an integer of 2 to 20, each of m and p is an integer of 1 to 5, and each of Z and W, which may be the same or different, is selected from the group consisting of a hydrogen atom, a heavy hydrogen atom, and an alkyl group.

Incidentally, in the light-emitting device according to the embodiment of the present invention, a sealing layer 5 is formed on the organic fluorescent layer 4. The sealing layer 5, which serves to prevent water from entering the light-emitting device from the outside, is formed of, for example, a trifluoro chloroethylene.

The method of manufacturing the light-emitting device according to the embodiment of the present invention will now be described.

In the first step, an LED chip used as a light-emitting section 2 was mounted within the recess of the LED frame 1, followed by connecting the electrode wiring to the LED chip 2. Then, particles 3b of the inorganic fluorescent substance were dispersed in a silicone monomer, followed by dripping the silicone monomer into the recess of the LED frame 1 so as to form the inorganic fluorescent layer 3. A mixture of an inorganic fluorescent substance of InGaN emitting luminescence of green having a wavelength of 520 nm and an inorganic fluorescent substance of InGaN emitting luminescence of blue light having a wavelength of 450 nm was used for forming the particles 3b of the inorganic fluorescent substance. Further, a heat treatment was applied to the inorganic fluorescent layer 3 so as to cure the silicone resin 3a by thermal polymerization. The heat treatment was performed at 150° C. for one hour.

Incidentally, the silicone resin containing the particles 3b of the inorganic fluorescent substance was left to stand for a prescribed time after the dripping, with the result that the silicone resin was cured. By allowing the silicone resin to be left to stand for a prescribed time, the fine particles 3b of the inorganic fluorescent substance were allowed to settle, with the result that it was possible to distribute unevenly the fine particles 3b of the inorganic fluorescent substance in the lower portion of the inorganic fluorescent layer 3. In this fashion, it is possible to control appropriately the emission efficiency of the inorganic fluorescent substance.

In the next step, the matrix polymer 4a containing particles 4b of the rare earth element complex was formed on the inorganic fluorescent layer 3 by the thermal compression bonding so as to form the organic fluorescent layer 4. It is possible to set the temperature for the thermal compression bonding at, for example, 120° C. In order to form the organic fluorescent layer 4 at a high yield, it is desirable to set the temperature for the thermal compression bonding in a manner to fall within a range of 70° C. to 200° C. It is also possible to employ the casting method for forming the organic fluorescent layer 4. To be more specific, an ink is prepared by adding particles 4b of the rare earth element complex and the matrix polymer 4a in a solvent. Then, the ink is cast so as to form an organic fluorescent layer containing the rare earth element complex on the inorganic fluorescent layer. The silicone resin layer and the organic fluorescent layer are unlikely to be mixed with each other even in the case of employing a molding method utilizing heating or a solvent. Such being the situation, the fluorescent layer can be formed by employing the method described above.

Further, the sealing layer 5 made of, for example, trifluoro chloroethylene resin is formed on the organic fluorescent layer 4 so as to carry out the sealing step of the light-emitting device, thereby obtaining the light-emitting device according to the first embodiment of the present invention.

The effect produced by the light-emitting device according to the first embodiment of the present invention will now be described.

In the light-emitting device (LED device) according to the first embodiment of the present invention, the second fluorescent layer containing an organic fluorescent substance is formed on the first fluorescent layer containing an inorganic fluorescent substance, and the organic fluorescent layer is positioned apart from the exciting light source. The particular construction makes it possible to obtain an LED device excellent in the color rendering properties, in the color purity and in the reliability for a long time. To be more specific, the light-emitting device according to the first embodiment of the present invention permits producing the function and effect pointed out in the following.

(1) Since the organic fluorescent layer 4 is positioned apart from the UV light source (LED chip 2), it is possible to suppress the deterioration of the organic fluorescent substance contained in the organic fluorescent layer 4.

(2) Since the inorganic fluorescent layer 3 is formed before formation of the organic fluorescent layer 4, it is possible to avoid the problem that the silicone radical attacks the organic fluorescent layer 4 in curing the silicone resin constituting the inorganic fluorescent layer 3.

It is possible to maintain the transparency of the organic fluorescent layer 4 because of effects (1) and (2) given above.

(3) Since the particles 3b of the inorganic fluorescent substance are collected in the vicinity of the LED chip 2, the emission intensity can be improved by the particles 3b of the inorganic fluorescent substance.

(4) The fluorine-based transparent polymer in the organic fluorescent layer 4 exhibits hydrophobic properties and a water repellency, with the result that an improvement in the sealing effect can be expected in the region above the LED chip 2.

(5) Since the fluorescent layers (i.e., the inorganic fluorescent layer 3 and the organic fluorescent layer 4) can be formed independently, white color adjustment can be performed easily.

(6) The thickness of the organic fluorescent layer can be adjusted. Because of this adjustment, it is possible to suppress UV leakage without being accompanied by a significant change in the color phase.

In order to confirm the effects produced by the first embodiment of the present invention, an experiment was conducted as follows. In the first step, the inorganic fluorescent layer 3, in which a silicone resin was used as the matrix polymer, was formed in a manner to fill ¾ of the depth of the recess of the LED frame 1. Then, the organic fluorescent layer 4, in which Cefral, manufactured by Central Glass Co., Ltd., was used as the matrix polymer, was formed on the inorganic fluorescent layer 3 in a manner to cover the remaining ¼ of the depth of the recess of the LED frame 1, thereby manufacturing an LED constructed as shown in FIG. 1B. Also, the inorganic fluorescent layer 3 was formed in a manner to fill ½ of the depth of the recess of another LED frame 1, followed by forming the organic fluorescent layer 4 on the inorganic fluorescent layer 3 in a manner to fill the remaining ½ of the depth of the recess of the LED frame 1, thereby manufacturing an LED constructed as shown in FIG. 1A. The fluorescent layers were made equal to each other in the charging amount of the fluorescent substance contained in each fluorescent layer regardless of the thickness of the fluorescent layer.

An acceleration test was applied to the LED's thus obtained so as to examine the change with time in the peak intensity of 612 nm of the wavelength. The peak intensity was standardized by the initial value, and the results are shown in Table 1. As shown in Table 1, the LED having a thick inorganic fluorescent layer 4 and a long distance between the light source (the light-emitting surface of the LED chip 2) and the organic fluorescent layer 4 was found to exhibit a better durability. It is possible to suppress the initial deterioration by using a laminate structure comprising the inorganic fluorescent layer 3 and the organic fluorescent layer 4 as in the first embodiment of the present invention. Particularly, it has been found that the initial deterioration can be suppressed prominently by arranging the organic fluorescent layer 4 apart from the light source, and that the deterioration thereafter can be suppressed to a low level.

TABLE 1

| | Peak intensity of 612 nm | | |
|---|---|---|---|
| | Initial | 10 hours | 500 hours |
| Matrix polymer | value | later | later |
| silicone | 1.00 | 0.11 | 0.11 |
| Cefral/silicone = 2:2 | 1.00 | 0.39 | 0.30 |
| Cefral/silicone = 1:3 | 1.00 | 0.75 | 0.74 |

The light-emitting device according to the first embodiment of the present invention is constructed such that the inorganic fluorescent layer 3 having a high refractive index, in which a silicone resin is used as the matrix polymer, and the organic fluorescent layer 4 having a low refractive index, in which Cefral (manufactured by Central Glass Co., Ltd.) was used as the matrix polymer, are laminated one upon the other. Incidentally, the silicone resin used in the inorganic fluorescent layer 3 has a refractive index of about 1.3 to 1.6. It is possible to permit the inorganic fluorescent layer 3 to have a refractive index higher than that of the organic fluorescent layer 4 by dispersing fine particles of the inorganic fluorescent substance or optional inorganic particles having a high refractive index in the silicone resin having the refractive index noted above.

It follows that it is possible to suppress the difference in the refractive index among the fluorescent layers and the air layer by decreasing successively the refractive indexes along the propagating route of the light generated from the LED chip 2, i.e., along the inorganic fluorescent layer, the organic fluorescent layer, and the outer space (air layer) in the order mentioned. As a result, it is possible to suppress the total reflection at the interface between the adjacent layers so as to enhance the light extraction efficiency.

It should also be noted that the propagation direction of the light emitted from the LED chip 2 is changed at the interface between the inorganic fluorescent layer 3 and the organic fluorescent layer 4 so as to be expanded outward. It follows that the light emitted from the LED chip 2 is widely diffused by the organic fluorescent layer 4 so as to improve the emission efficiency at the organic fluorescent layer 4. It follows that it is possible to obtain a light-emitting device of a high efficiency. Further, since the light emitted from the LED chip 2 is emitted to the outside of the light-emitting device at a wide angle, it is possible to provide a light-emitting device adapted for use in, for example, indoor illumination.

### Comparative Example 1

As a Comparative Example, manufactured was an LED comprising a fluorescent layer 13 prepared by dispersing both the particles 3b of the inorganic fluorescent substance and the particles 4b of the organic fluorescent substance in a silicone resin 13a, as shown in FIG. 1C. The charging amounts of the particles 3b of the inorganic fluorescent substance and the particles 4b of the organic fluorescent substance were equal to those of the fluorescent substances shown in Table 1. An acceleration test was also applied to the LED thus obtained so as to examine the change with time in the peak intensity of 612 nm of the wavelength. As shown in Table 1, an initial deterioration was prominent in this LED, and the organic fluorescent substance was substantially deactivated in this stage.

### Comparative Example 2

The initial brightness of the LED was examined, covering the case where the fluorescent layer was of a single layer structure and the case where an inorganic fluorescent layer and an organic fluorescent layer were laminated one upon the other in a thickness ratio of 2:2. Table 2 shows the result of comparison of the initial brightness. As shown in Table 2, a fluorescent layer of a single layer structure was formed on the LED chip by dispersing a green-emitting inorganic fluorescent substance (InGaN, 520 nm), a blue-emitting inorganic fluorescent substance (InGaN, 450 nm) and the europium complex described previously in a silicone resin.

It was impossible to obtain good characteristics from the LED of this particular construction. It is considered reasonable to understand that the europium complex is deteriorated in the curing process of the silicone resin. Also, the exciting light is shielded by the scattering of the light caused by the fine particles of the inorganic fluorescent substance, with the result that the light emission from the europium complex is suppressed. The fine particles of the inorganic fluorescent substance are distributed relatively unevenly in the lower portion of the fluorescent layer, whereas the europium complex particles are uniformly distributed within the fluorescent layer. Because of such a difference in the distributing state, optimization of the characteristics is considered to be rendered complex. Also, it is possible for the presence of the fine particles of the inorganic fluorescent substance to deteriorate the organic fluorescent substance catalytically.

On the other hand, a fluorescent layer of a single layer structure was formed on the LED chip as above, except that Cefral, which is a fluorine-based polymer manufactured by Central Glass Co., Ltd., was substituted for the silicone resin. The LED of the particular construction was also incapable of exhibiting good characteristics. The reason for failure to obtain good characteristics is equal to that in the case where particles of both an inorganic fluorescent substance and an organic fluorescent substance were dispersed in the silicone resin. Further, the particles of the inorganic fluorescent substance are dispersed uniformly in the fluorine-based resin so as to cause the brightness of the light-emitting device to tend to be decreased, resulting in failure to obtain good characteristics.

On the other hand, in the case of employing a laminate structure comprising an inorganic fluorescent layer and an organic fluorescent layer as in the first embodiment of the present invention, it can be seen that it is possible to provide an LED having an excellent initial brightness.

TABLE 2

| | Initial luminous |
|---|---|
| Matrix polymer | intensity/mcd |
| Silicone | 360 |
| Cefral | 280 |
| Cefral/silicone | 420 |

### Comparative Example 3

A transparent fluorescent layer was formed on the LED chip by using the fluorine-based transparent polymer (Cefral manufactured by Central Glass Co., Ltd.) having the europium complex particles 4b dispersed therein, with the result that an improvement in the emission characteristics was recognized, compared with the fluorescent layer prepared by using the matrix polymer having red-emitting inorganic fluorescent substance dispersed therein.

It is considered reasonable to understand that, in the case of the transparent light-emitting layer prepared by using the europium complex particles, light scattering is not generated so as to markedly improve the light extraction efficiency, which greatly contributes to the improvement in the characteristics.

However, it has been found that, if the light-emitting device is lit for a long time, the region in the vicinity of the UV light source is deteriorated so as to be colored brown. In order to prepare a transparent light-emitting layer, it is necessary to select a specific fluorine-based polymer in view of the compatibility between the rare earth element complex and the fluorine-based polymer. It is considered reasonable to understand that, since that portion of the fluorine-based polymer which serves to improve the compatibility with the rare earth element complex is low in its resistance to UV and heat, the deterioration described above is generated.

### Comparative Example 4

The organic fluorescent layer 4 was formed as in the first embodiment of the present invention. In this case, the ratio of the europium complex to the fluorine-based polymer 4a was changed in various fashions by, for example, preparing an ink for the organic fluorescent layer 4. Where the ratio of the europium complex to the fluorine-based polymer was lower than 5% by weight, the amount of the fluorescent substance was insufficient so as to lower the emission brightness to 2 mcd. On the other hand, where the ink was adjusted so as to permit the ratio noted above to exceed 80% by weight, the dispersion capability of the fluorescent substance was impaired. Further, the fluorescent substance failed to be supported completely in the matrix polymer and was separated. Such being the situation, it was impossible to use as a fluorescent layer. It is more desirable for the ratio of the europium complex to the fluorine-based polymer to fall within a range of 10 to 50% by weight.

### Comparative Example 5

The distance between the organic fluorescent layer 4 and the near-ultraviolet light source (the light-emitting surface of the LED chip 2) was changed in the light-emitting device according to the first embodiment of the present invention so as to examine the changes in the initial brightness and in the half-life. Table 3 shows the changes in the initial brightness and in the half-life thus obtained. As shown in Table 3, where the distance between the organic fluorescent layer 4 and the light-emitting surface of the LED chip 2 was shorter than 10 μm, the initial brightness was lowered, and the half-life was also decreased markedly. It has been found that, in the region where the output of the exciting light was strong, the organic fluorescent layer was deteriorated so as to be colored brown, indicating that the brightness was prominently lowered. In view of the situation that the exciting energy is lowered with increase in the distance between the organic fluorescent layer 4 and the light-emitting surface of the LED chip 2, it is desirable for the upper limit of the distance between the organic fluorescent layer 4 and the light-emitting surface of the LED chip 2 to be set at about 1000 μm.

TABLE 3

| Distance between | Initial | |
|---|---|---|
| organic fluorescent | luminous | |
| layer and light | intensity/ | Half-life/ |
| source/μm | mcd | time |
| 5 | 320 | 100 |
| 10 | 400 | 500 |
| 100 | 480 | 700 |

### Second Embodiment

It is possible to manufacture a light-emitting device having a laminate structure comprising an inorganic fluorescent layer and an organic fluorescent layer by using at least one of a terbium complex and a erbium complex in place of the europium complex used in the first embodiment of the present invention. In this case, the organic fluorescent layer is prepared by dispersing particles of at least one of the terbium complex and the erbium complex or a mixture of particles consisting of the terbium complex particles, the erbium complex particles and the europium complex particles, in the fluorine-based polymer 4a. For example, the LED comprises an inorganic fluorescent layer containing an blue-emitting inorganic fluorescent substance (InGaN, 450 nm) and an organic fluorescent layer prepared by dispersing the particles of both the europium complex (red-emitting) and the terbium complex (green-emitting) in, for example, an acrylic fluorocarbon resin. It is also possible to manufacture an LED device comprising an inorganic fluorescent layer containing particles of a blue-emitting inorganic fluorescent substance (InGaN, 450 nm) and a red-emitting inorganic fluorescent substance (La₂O₂S:Eu) and an organic fluorescent layer prepared by dispersing particles of a terbium complex (green-emitting) in, for example, an acrylic fluorocarbon resin. It is possible to obtain the emission of a white light by using such an organic fluorescent layer containing a rare earth element complex so as to make it possible to improve markedly the color rendering properties of the light-emitting device having a laminate structure comprising an inorganic fluorescent layer and an organic fluorescent layer.

### Third Embodiment

In the third embodiment of the present invention, the surface of the inorganic fluorescent layer 3 included in the light-emitting device according to the first embodiment of the present invention is shaped concave or convex. FIGS. 2A and 2B are cross sectional views schematically showing the construction of the light-emitting device according to the third embodiment of the present invention. FIG. 2A covers the case where the surface of the inorganic fluorescent layer 3 is shaped concave. On the other hand, FIG. 2B covers the case where the surface of the inorganic fluorescent layer 3 is shaped convex.

In the light-emitting device shown in FIG. 2A, an inorganic fluorescent layer 23 and an organic fluorescent layer 24 are laminated one upon the other on the LED chip 2 arranged within the recess of the LED frame 1. The ratio in average thickness of the inorganic fluorescent layer 23 to the organic fluorescent layer 24 is 1:3. The inorganic fluorescent layer 23 is prepared by using a silicone resin 23a having the particles 23b containing the green-emitting inorganic fluorescent substance (InGaN, 520 nm) and the blue-emitting inorganic fluorescent substance (InGaN, 450 nm) dispersed therein and occupies ½ of the recess of the LED frame 1. The surface of the inorganic fluorescent layer 23 is shaped concave. It is possible to set the curvature radius of the concave surface of the inorganic fluorescent layer 23 to fall within a range of, for example, about 1.0 mm to 100 mm, desirably to fall within a range of 1.0 mm to 30 mm. On the other hand, the organic fluorescent layer 24 is formed of a fluorine-based polymer 24a containing europium complex particles 24b and occupies the remaining ½ of the recess of the LED frame 1. It is possible to use the fluorine-based polymer 24a and the europium complex particles 24b equal to those used in the first embodiment of the present invention described previously.

According to the light-emitting device shown in FIG. 2A, the refractive index of the inorganic fluorescent layer 23 is higher than that of the organic fluorescent layer 24 as in the first embodiment of the present invention described previously. In addition, the surface of the inorganic fluorescent layer 23 is shaped concave in the light-emitting device shown in FIG. 2A. As a result, the propagation direction of the light emitted from the LED chip 2 is changed at the interface between the inorganic fluorescent layer 23 and the organic fluorescent layer 24 so as to be expanded outward. The expansion of the light is more prominent than in the first embodiment described previously. The brightness, denoting the emission intensity in the linear direction, and the luminous flux measured by the integrating sphere were examined, with the result that the brightness was found to be 300 mcd and the value of the luminous flux was 1120 mlm (see Table 4).

For comparison, Table 4 also shows the brightness and the luminous flux in the case of using an inorganic fluorescent layer having a flat surface. According to the light-emitting device of the third embodiment of the present invention, the light emitted from the LED chip 2 is diffused into the organic fluorescent layer 24 more broadly than in the first embodiment. As a result, it is possible to improve the emission efficiency at the organic fluorescent layer 24 so as to make it possible to obtain a light-emitting device having a high efficiency. Also, since the light emitted from the LED chip 2 is diffused to the outside of the light-emitting device in a broader angle, the third embodiment provides a light-emitting device adapted for use in, for example, indoor illumination.

TABLE 4

| | luminous | |
|---|---|---|
| | intensity/ | Luminous flux/ |
| | mcd | mlm |
| Flat laminate | 320 | 960 |
| interface of | | |
| Cefral/silicone | | |
| Concave | 300 | 1120 |
| laminate | | |
| interface of | | |
| Cefral/silicone | | |
| Convex laminate | 340 | 880 |
| interface of | | |
| Cefral/silicone | | |

On the other hand, in the light-emitting device shown in FIG. 2B, an inorganic fluorescent layer 33 and an organic fluorescent layer 34 are laminated in the order mentioned as viewed from the lower layer on the LED chip 2 arranged within the recess of the LED frame 1. The ratio in average thickness of the inorganic fluorescent layer 33 to the organic fluorescent layer 34 is 3:1. The inorganic fluorescent layer 33 was prepared by using a silicone resin 33a having the particles 33b containing the green-emitting inorganic fluorescent substance (InGaN, 520 nm) and the blue-emitting inorganic fluorescent substance (InGaN, 450 nm) dispersed therein and occupies ½ of the recess of the LED frame 1. The surface of the inorganic fluorescent layer 33 is shaped convex. It is possible to set the curvature radius of the convex surface of the inorganic fluorescent layer 33 to fall within a range of, for example, 1.0 mm to 100 mm, preferably to fall within a range of about 1.0 mm to 30 mm. On the other hand, the organic fluorescent layer 34 is formed of a fluorine-based polymer 34a containing europium complex particles 34b and occupies the remaining ½ of the recess of the LED frame 1. It is possible to use fluorine-based polymer 34a and europium complex particles 34b substantially equal to those used in the first embodiment of the present invention described previously.

According to the light-emitting device shown in FIG. 2B, the refractive index of the inorganic fluorescent layer 33 is higher than that of the organic fluorescent layer 34 in the first embodiment described previously, and the surface of the inorganic fluorescent layer 33 is shaped convex. As a result, the propagation direction of the light emitted from the LED chip 2 is changed at the interface between the inorganic fluorescent layer 33 and the organic fluorescent layer 34 so as to be converged inward. The brightness, denoting the light-emitting intensity in the linear direction, and the value of the luminous flux measured by the integrating sphere were examined, with the result that the brightness was found to be 340 mcd and the value of the luminous flux was found to be 880 mlm as shown in Table 4. According to the light-emitting device noted above, the light emitted from the LED chip 2 is propagated to the outside of the light-emitting device with a good directivity. It follows that the light-emitting device is adapted for use in, for example, a flashlight of a camera.

### Fourth Embodiment

The fourth embodiment is directed to a light-emitting device substantially equal to that of the first embodiment, except that a separating layer 41 for separating the inorganic fluorescent layer 33 and the organic fluorescent layer 4 included in the light-emitting device according to the first embodiment is formed between the inorganic fluorescent layer 3 and the organic fluorescent layer 4.

FIG. 2C is a cross sectional view schematically showing the construction of the light-emitting device according to the fourth embodiment of the present invention. As shown in the drawing, a separating layer 41 for separating the inorganic fluorescent layer 3 and the organic fluorescent layer 4 is formed between the inorganic fluorescent layer 3 and the organic fluorescent layer 4. Where, for example, a thermally polymerizable silicone resin is used for forming the inorganic fluorescent layer 3 and a thermoplastic Cefral, manufactured by Central Glass Co., Ltd., is used for forming the organic fluorescent layer 4, it is advisable to form the separating layer 41 by casting a polymer dissolved in a solvent. Where the separating layer 41 is formed in this fashion, it is possible to prevent the inorganic fluorescent layer 3, the organic fluorescent layer 4, and the separating layer 41 from being mixed with each other. It follows that it is possible to form the separating layer 41 satisfactorily. Such being the situation, it is possible to use, for example, an acrylic resin or a polyester resin for forming the separating layer 41. It is possible to improve the characteristics of the light-emitting device by selecting the material of the separating layer 41 in view of, for example, the adhesion properties in accordance with the matrix polymers used in the inorganic fluorescent layer 3 and the organic fluorescent layer 4.

In the embodiment described above, the inorganic fluorescent layer 3 and the organic fluorescent layer 4 are less likely to be mixed with each other. However, it is possible for the inorganic fluorescent layer 3 and the organic fluorescent layer 4 to be mixed with each other. The mixing is caused by the unevenness in the manufacturing process, and increases with use over time so as to deteriorate the fluorescent layers, leading to the problem that the brightness is lowered. However, in the light-emitting device according to the fourth embodiment of the present invention, the separating layer 41 is formed between the inorganic fluorescent layer 3 and the organic fluorescent layer 4 so as to prevent, without fail, the inorganic fluorescent layer 3 and the organic fluorescent layer 4 from being mixed with each other. It follows that it is possible to overcome the problem that the fluorescent layers are deteriorated so as to lower the brightness of the light-emitting device.

### Fifth Embodiment

In the light-emitting device according to the fifth embodiment of the present invention, at least one of the inorganic fluorescent layer and the organic fluorescent layer has a refractive index distribution such that the refractive index is decreased with increase in the distance from the LED chip 2 in the thickness direction of the fluorescent layer. The light-emitting device for this embodiment will now be described with reference to FIGS. 1A and 1B.

As shown in FIGS. 1A and 1B, the inorganic fluorescent layer 3 and the organic fluorescent layer 4 are laminated one upon the other in the order mentioned as viewed from below. The silicone resin 3a and the particles 3b of the inorganic fluorescent substance contained the inorganic fluorescent layer 3 are equal to those used in the first embodiment described previously. Also, the fluorine-based polymer and the europium complex particles forming the organic fluorescent layer 4 are similar to those used in the first embodiment described previously. Incidentally, it is possible to use particles of a rare earth element complex other than the particles of the europium complex, as in the second embodiment described previously.

The refractive index in the lower region of the inorganic fluorescent layer 3, which is positioned close to the LED chip 2, is higher than the refractive index in the upper region of the inorganic fluorescent layer 3. This particular distribution of refractive index can be achieved by the method described in the following. Specifically, in forming the silicone resin layer, the inorganic fluorescent substance is added. In this step, compounds having a high refractive index, such as SiO₂, Al₂O₃, Zr₂O₃, Y₂O₃, TiO₂, B₂O_{3 and CaCO}₃, are also added as required together with the inorganic fluorescent substance. After the resultant mixture is left to stand for a prescribed time long enough to permit the additives to be settled in a manner to form a desired concentration distribution in the up-down direction, the thermal polymerization to form the silicone resin is carried out. As a result, it is possible to form the inorganic fluorescent layer 3 in which the particles of the inorganic fluorescent substance are unevenly distributed in the lower region, and the additives having a high refractive index, which are used as required, are also unevenly distributed in the lower region of the inorganic fluorescent layer 3.

As a result, formed is the inorganic fluorescent layer 3 in which the average distribution of the refractive index is gradually increased from the upper region toward the lower region. It is also possible to form the inorganic fluorescent layer in which the average distribution of the refractive index is gradually increased from the upper region toward the lower region by using, in combination, silicone resins differing from each other in refractive index, and by laminating these silicone resin layers one upon the other. Incidentally, it is possible for the refractive index to be changed stepwise or to be graded, e.g., to be increased monotonously.

In the light-emitting device according to the fifth embodiment of the present invention, the refractive index of the inorganic fluorescent layer 3 is decreased with increase in the distance from the LED chip 2, with the result that the light emitted from the LED chip 2 is unlikely to be subjected to total reflection at the interface between the inorganic fluorescent layer 3 and the organic fluorescent layer 4. To be more specific, in the light-emitting device according to the first embodiment of the present invention, the amount of light emitted from the LED chip 2 and subjected to total reflection toward the inside at the interface between the inorganic fluorescent layer and the organic fluorescent layer is changed by the difference in refractive index between the inorganic fluorescent layer and the organic fluorescent layer. As a result, the light extraction efficiency is affected in some cases. In the fifth embodiment of the present invention, the refractive index within the silicone resin 3a is decreased with increase in the distance from the LED chip 2 so as to make it possible to moderate the difference in refractive index between the inorganic fluorescent layer and the organic fluorescent layer. As a result, it is possible to suppress total reflection, compared with the light-emitting device according to the first embodiment of the present invention, so as to maintain a good light extraction efficiency.

It is also possible to control the distribution of the refractive index within the organic fluorescent layer. For example, the refractive index in the lower region of the fluorine-based polymer 4a, which is positioned closer to the LED chip 2, can be made higher than the refractive index in the upper region of the fluorine-based polymer 4a. This particular construction can be formed by the method described in the following. Specifically, in copolymerizing the fluorine-based acrylic monomer and the methacrylic monomer for forming the fluorine-based polymer, the reactants are heated, for example, from below. In this case, the copolymer rich in acrylic monomer units having a high reactivity is formed first, and the concentration of the acrylic monomer units is gradually decreased from the lower region toward the upper region of the fluorine-based polymer layer thus formed. In this case, the refractive index is low in the region having a high fluorination rate, and the refractive index is decreased with increase in the fluorination rate. The organic fluorescent layer 4, in which the distribution of the average refractive index is gradually increased from the upper region toward the lower region, can be formed by applying a thermal compression bonding method, a thermal transfer method, or a thermal molding method to the film fluorine-based polymer thus obtained, which has a refractive index gradient. Incidentally, it is possible for the refractive index to be changed stepwise or for the change in the refractive index to be graded, e.g., to be increased monotonously.

Incidentally, the present invention is not limited to the embodiments described above. For example, it is possible to use various kinds of silicone resins. In manufacturing the silicone resin, it is possible to mix a silicone monomer having a polymerizable portion such as ˜Si—CH═CH₂ with a radical-forming compound such as an organic peroxide and to heat the monomer mixture so as to achieve a crosslinking polymerization. It is also possible to use a silicone material that can be crosslinked by irradiation with an ultraviolet light. Concerning the silicone portion, it is possible to use denatured silicone materials prepared by copolymerization with various organic materials in order to improve the characteristics such as the compatibility with the additive, the adhesive properties and the mechanical characteristics.

Incidentally, each of the embodiments described above is directed to a light-emitting section emitting an ultraviolet light. However, it is also possible to use a light-emitting section emitting a visible light, which uses an organic or inorganic fluorescent substance that emits luminescence upon excitation with light other than the ultraviolet light, e.g., upon excitation with a visible light.

The present invention is not limited to the embodiments described above as they are. In working the technical idea of the present invention, the constituting factors of the present invention can be modified in various fashions within the technical scope of the present invention. Also, various inventions can be achieved by combining appropriately a plurality of constituting factors disclosed in the embodiments of the present invention. For example, it is possible to delete some constituting factors from all the constituting factors disclosed in the embodiments described above. Further, it is possible to combine appropriately the constituting factors bridging different embodiments of the present invention described above.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A light-emitting device, comprising:
a light-emitting element configured to emit light;
a first fluorescent layer comprising an inorganic fluorescent substance, formed on the light-emitting element and having a first refractive index; and
a second fluorescent layer comprising an organic fluorescent substance, formed above the first fluorescent layer and having a second refractive index.

2. The light-emitting device according to claim 1, wherein the first refractive index is higher than the second refractive index.

3. The light-emitting device according to claim 1, wherein the upper surface of the first fluorescent layer is shaped concave.

4. The light-emitting device according to claim 3, wherein the curvature radius of the upper surface of the first fluorescent layer falls within a range of 1.0 mm to 100 mm.

5. The light-emitting device according to claim 1, wherein the upper surface of the first fluorescent layer is shaped convex.

6. The light-emitting device according to claim 5,wherein the curvature radius of the upper surface of the first fluorescent layer falls within a range of 1.0 mm to 100 mm.

7. The light-emitting device according to claim 1, wherein the first fluorescent layer comprises as a matrix a silicone resin prepared by thermal polymerization.

8. The light-emitting device according to claim 1, wherein the second fluorescent layer comprises a rare earth element complex and a matrix polymer.

9. The light-emitting device according to claim 8, wherein the rare earth element complex is represented by the following general formula: 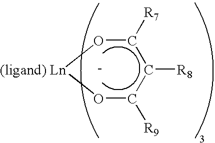
where Ln denotes a rare earth element, each of R₇ and R₉ is selected from the group consisting of a linear or branched alkyl group, a linear or branched alkoxy group, a phenyl group, a biphenyl group, a naphthyl group, a hetero ring group, and derivatives thereof, and R₈ is selected from the group consisting of a halogen atom, a heavy hydrogen atom, and a linear or branched aliphatic hydrocarbon group having 1 to 22 carbon atoms.

10. The light-emitting device according to claim 8, wherein the rare earth element complex is represented by the following general formula: 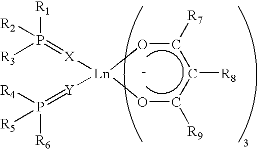
where Ln denotes a rare earth element, each of X and Y is an atom selected from the group consisting of O, S and Se, each of R₁ to R₆ is selected from the group consisting of a linear or branched alkyl group having not more than 20 carbon atoms, a linear or branched alkoxy group having not more than 20 carbon atoms, a phenyl group, a biphenyl group, a naphthyl group, a hetero ring group, and derivatives thereof, the combination of R₁ to R₃ differing from the combination of R₄ to R₆, each of R₇ and R₉ is selected from the group consisting of a linear or branched alkyl group, a linear or branched alkoxy group, a phenyl group, a biphenyl group, a naphthyl group, a hetero ring group, and derivatives thereof, and R₈ is selected from the group consisting of a halogen atom, a heavy hydrogen atom, and a linear or branched aliphatic hydrocarbon group having 1 to 22 carbon atoms.

11. The light-emitting device according to claim 8, wherein the matrix polymer is selected from the group consisting of polytetrafluoro ethylene, tetrafluoroethylene-perfluoroalkyl vinyl ether copolymer, tetrafluoroethylene-hexafluoropropylene copolymer, tetrafluoroethylene-ethylene copolymer, polyvinylidene fluoride, poly-chlorotrifluoroethylene, fluoroethylene-vinyl ether copolymer, copolymer between the fluorocarbon resin and acrylic resin, and a fluorinated acrylic resin.

12. The light-emitting device according to claim 11, wherein the matrix polymer is selected from the group consisting of fluoroethylene-vinyl ether copolymer, a copolymer between fluorocarbon resin and acrylic resin, and a fluorinated acrylic resin.

13. The light-emitting device according to claim 8, wherein a ratio in weight of the rare earth element complex to the matrix polymer of the second fluorescent layer falls within a range of 5 to 80% by weight.

14. The light-emitting device according to claim 13, wherein the ratio in weight of the rare earth element complex to the matrix polymer of the second fluorescent layer falls within a range of 10 to 50% by weight.

15. The light-emitting device according to claim 1, wherein the first fluorescent layer comprises a silicone resin as a matrix, and the second fluorescent layer comprises a fluorinated polymer as a matrix.

16. The light-emitting device according to claim 1, wherein first region of the first fluorescent layer which is positioned close to the light-emitting element has a higher refractive index than second region of the first fluorescent layer which is remote from the light-emitting element.

17. The light-emitting device according to claim 1, wherein first region of the second fluorescent layer which is positioned close to the light-emitting element has higher refractive index than second region of the second fluorescent layer which is remote from the light-emitting element.

18. The light-emitting device according to claim 1, further comprising a separating layer positioned between the first fluorescent layer and the second fluorescent layer, the separating layer separating the first fluorescent layer and the second fluorescent layer from each other.

19. The light-emitting device according to claim 1, wherein the distance between the second fluorescent layer and the light-emitting element is not shorter than 10 μm.

20. The light-emitting device according to claim 1, wherein the light-emitting element is formed of a light-emitting diode element.
